(19) United States
(12) Patent Application Publication
(10) Pub. No.: US 2002/0182856 A1
(43) Pub. Date: Dec. 5, 2002

(54) Method for forming a contact window with low resistance

(76) Inventor: Ching-Yu Chang, Yuan-Shan Hsiang (TW)

Correspondence Address: POWELL, GOLDSTEIN, FRAZER & MURPHY LLP, P.O. BOX 97223, WASHINGTON, DC, 20090-7223, US

(21) Appl. No.: 09/872,304

(22) Filed: Jun. 1, 2001

(51) Int. Cl. H01L 21/4763; H01L 21/44

(52) U.S. Cl. 438/639; 438/675; 438/644

(57) ABSTRACT

A method for forming a contact window with low resistance. The method at least includes the following steps. First of all, a dielectric layer is formed over a substrate, in which the substrate having a contact region where the metal contact will be formed thereon. Then, a first barrier layer is deposited over the dielectric layer, and a patterned photoresist is formed to defined a contact hole. Next, the first barrier layer and the dielectric layer are etched to expose portion of the substrate by using the photoresist as a mask thereby a contact hole is formed in the dielectric layer, wherein the exposed substrate has a conductive region. Then, a second conformal barrier layer is deposited on the first barrier layer and in the contact hole, the second conformal barrier layer is etched to exposed the conductive region to form a spacer on sidewalls of in the contact hole. Finally, the contact region opening is filled with a metal layer to complete electrical connections.

### BACKGROUND OF THE INVENTION

1. Field of the Invention

The present invention generally relates to a method for forming a semiconductor device, and more particularly to a method for forming a contact window with low resistance.

2. Description of the Prior Art

With the progress in the semiconductor integrated circuits, from LSI (large scale integration), VLSI (very large scale integration), to ULSI (ultra large scale integration), the integrity of the integrated circuits rises in an amazing rate. Taking DRAM (dynamic random access memories ) for example, the increasing integrity in manufacturing extends the capacity of a single DRAM chip to step from earlier 4 megabit to 16 megabit, and further to 256 megabit or even higher. The increasing integrity of integrated circuits generates numerous challenges with semiconductor manufacturing process. Every element needs to be formed within smaller area without influencing the characteristics and operations of the integrated circuits. One important challenge is in writing technology for forming metal connections within smaller space with uncompromising electric characteristics.

Referring to FIG. 1, first, the inter-metal dielectric (IMD) or inter-level dielectric (ILD) layer 102 is formed over a substrate 100 which comprises conductive region may be copper, aluminum, or silicide. The dielectric layer 102 is may be oxide, phosphosilicate glass, borophosilicate glass, and borophosphosphosilicate glass. Then, a contact hole is formed in the dielectric layer 102. Next, the conformal barrier layer 104 is deposited over the dielectric layer 102 by CVD method. The conformal barrier layer 104 is formed on the dielectric layer 102 and the contact hole. The conformal barrier layer 104 is may be titanium (Ti), and titanium nitride (TiN) Next, the metal layer 106, with a conductive material to contact the contact region in the substrate 100, is formed to fill the contact hole. The metal layer 106 in the contact opening can be electronically in contact with the conductive region in the substrate. However, there was an interval of the conformal barrier layer 104 between the metal layer 106 and the substrate 100 to cause contact hole high resistance phenomenon. The contact hole has a higher resistance. The power is higher when the current ran through the contact hole according to the theory of P=IR². The temperature raise up to a certain extend and cause circuit open issue.

For the foregoing reasons, there is a necessary for a method for forming a contact window with low resistance to reduce resistance issue. Reducing contact resistance can increase not only reliability but also performance electric result of the device

### SUMMARY OF THE INVENTION

In accordance with the present invention, a method for forming a contact window with low resistance is provided that resistance issue in conventional process is substantially can be is reduced.

One of the objectives of the present invention is to provide a method to form a contact window with low resistance the conductivity between the layer and the layer.

Another of the objective of the present invention is to provide a method to form a contact window with low resistance to decrease the ion diffusion contamination of metal ion between into the layer and metal layer.

In order to achieve the above objectives, the present invention provides a method for forming a contact window with low resistance. The method at least includes the following steps. First of all, a dielectric layer is formed over a substrate, in which the substrate having a contact region where the metal contact will be formed thereon. Then, a first barrier layer is deposited over the dielectric layer, and a patterned photoresist is formed to define a contact hole. Next, the first barrier layer and the dielectric layer are etched to expose portion of the substrate by using the photoresist as a mask thereby a contact hole is formed in the dielectric layer, wherein the exposed substrate has a conductive region. Then, a second conformal barrier layer is deposited on the first barrier layer and in the contact hole, the second conformal barrier layer is etched to exposed the conductive region to form a spacer on sidewalls of in the contact hole. Finally, the contact region opening is filled with a metal layer to complete electrical connections.

### BRIEF DESCRIPTION OF THE DRAWINGS

The foregoing aspects and many of the attendant advantages of this invention will become more readily appreciated as the same becomes better understood by referring to the following detailed description, when taken in conjunction with the accompanying drawings, wherein:

FIG. 1 is cross-sectional views of a method for forming a contact window in the prior art;

FIG. 2A to FIG. 2E are cross-sectional views of a method for forming a contact window with low resistance in accordance with one embodiment of the present invention.

### DESCRIPTION OF THE PREFERRED EMBODIMENT

Some embodiments of the invention will now be described in greater detail. Nevertheless, it should be recognized that the present invention can be practiced in a wide range of other embodiments besides those explicitly described here; the scope of the present invention is expressly not limited except as specified in the accompanying claims.

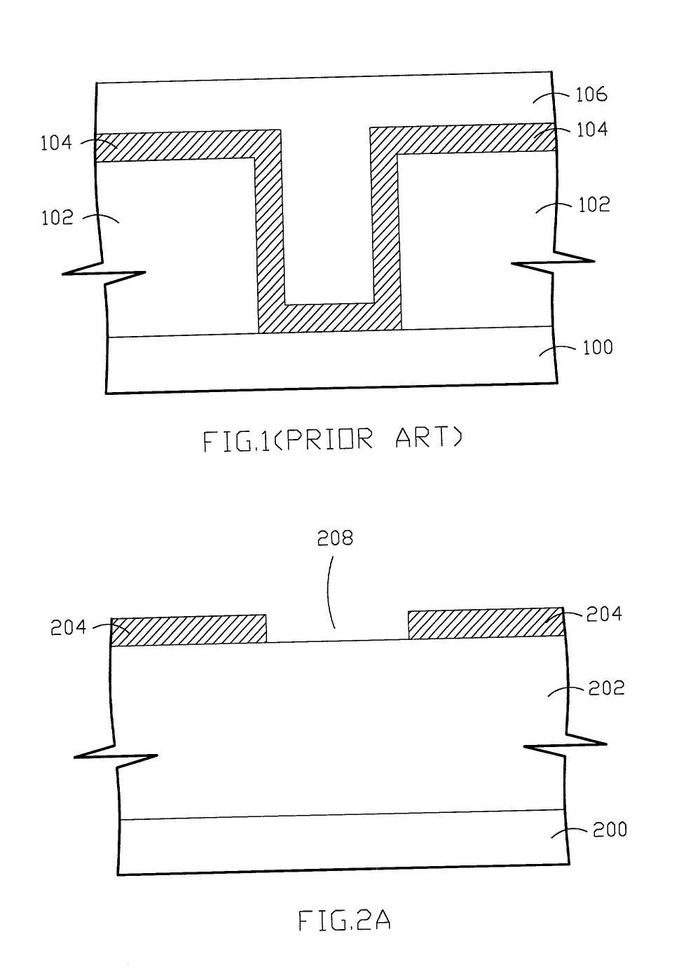

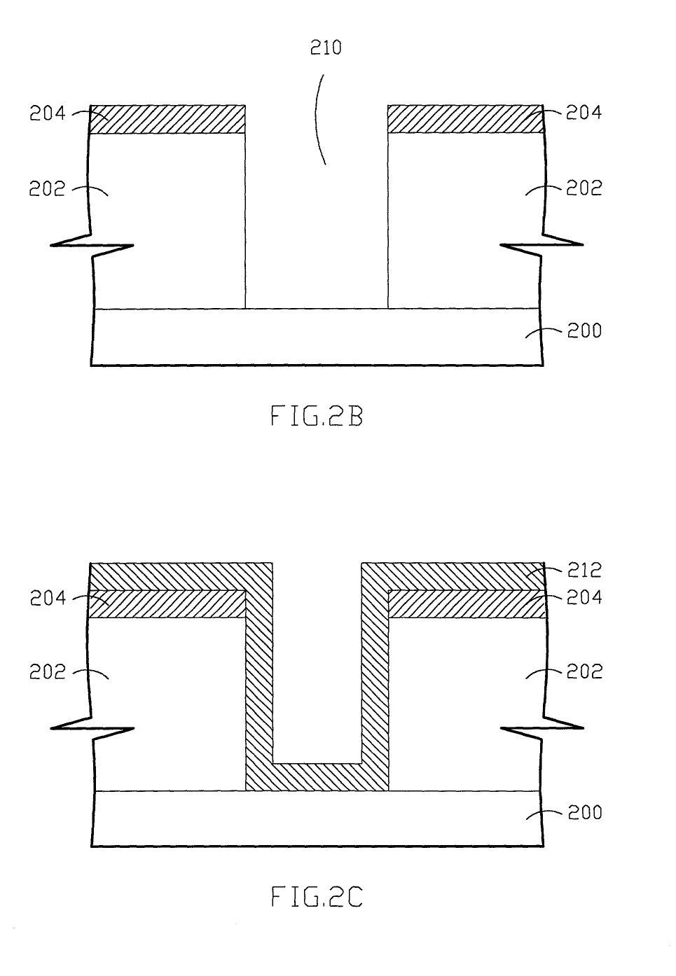

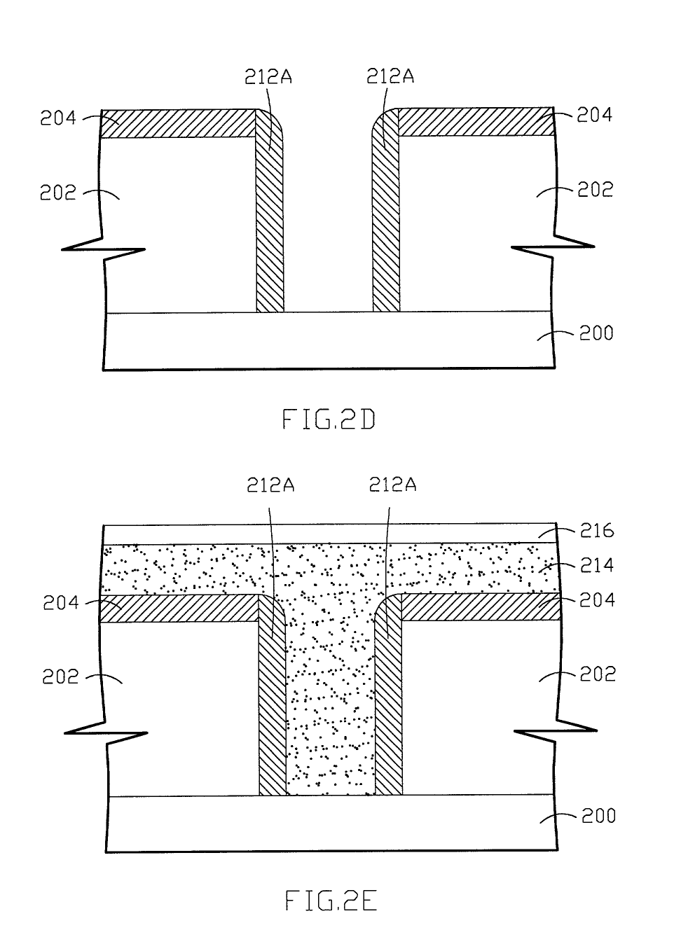

FIG. 2A to FIG. 2E are cross-sectional views of a method for forming a contact window with low resistance in accordance with one embodiment of the present invention.

Referring to FIG. 2A, the inter-metal dielectric (IMD) or inter-level dielectric (ILD) layer 202 is formed over a substrate 200 which comprises conductive region may be copper, aluminum, or silicide. The dielectric layer 202 is may be oxide, phosphosilicate glass, borophosilicate glass, and borophosphosphosilicate glass. In the embodiment, material of this layer is preferable oxide Next, the first barrier layer 204 with a thickness about 100 angstroms is deposited over the dielectric layer 202 by CVD method. The first barrier layer 204 is may be titanium (Ti), titanium nitride (TiN) tantalum nitride (TaN), tantalum tungsten (TaW), silicon nitride (Si₃N₄), and silicon oxynitride (SiON). In the embodiment, material of this layer is preferable silicon nitride(Si₃N₄).The first barrier layer 204 has an opening 208 over the contact region, because a conventional lithography process is performed on the barrier layer 204.

Referring to FIG. 2B, the dielectric layer 202 is etched anisotropically to expose a portion of the substrate 200. The etching step uses the barrier layer 204 as a mask, and the expose substrate 200 is the conductive region described in the FIG. 2A. Then, a contact hole 210 is formed in the dielectric layer 202.

Referring to FIG. 2C, the second conformal barrier layer 212 is deposited over the first barrier layer 204 and in the contact hole 210 by CVD method. The second conformal barrier layer 212 with a thickness between 100 angstroms and 500 angstroms. In the embodiment, thickness of this layer is preferable 100 angstroms. The second conformal barrier layer 212 is may be titanium (Ti), titanium nitride (TiN), tantalum nitride (TaN), tantalum tungsten (TaW), silicon nitride (Si₃N₄), and silicon oxynitride (SiON). In the embodiment, material of this layer is preferable silicon nitride (Si₃N₄).

Referring to FIG. 2D, the second conformal barrier layer 212 is etched anisotropically to expose a portion of the substrate 200. The second conformal barrier layer 212 to expose the conductive region and to form a spacer 212A on sidewalls of in the contact hole 210.

Referring to FIG. 1E, the metal layer 214, with a conductive material to contact the contact region in the substrate, is formed to fill the contact hole 210. The metal layer 214 in which conductive region may be comprises copper or aluminum. Passivation layer 216 completes the integrated circuit device.

Method for forming a contact window with low resistance using the above explained method, has the following advantages:

1. The present invention is to provide a method to form a contact window with low resistance to increase the conductivity between the metal layer and another meal the layer.

2. The present invention is to provide a method to form a contact window with low resistance to decrease the ion diffusion contamination of metal ion between into the layer and metal layer.

Although specific embodiment have been illustrated and described, it will be obvious to those skilled in the art that various modifications may be made without departing from what is intended to be limited solely by the appended claims

What is claimed is:

1. A method of fabricating a metal contact plug in a contact hole , the method comprising the steps of:
forming a dielectric layer over a substrate, said substrate having a contact region where said metal contact plug will be formed thereon;
depositing a first barrier layer over said dielectric layer;
forming a patterned photoresist to define a contact hole;
etching said first barrier layer and said dielectric layer to expose a portion of said substrate by using said photoresist as a mask;
forming a contact hole in said dielectric layer, wherein the exposed substrate has a conductive region;
depositing a second conformal barrier layer on said first barrier layer and in said contact hole;
etching said second conformal barrier layer to expose said substrate and to form a spacer on sidewalls of in said contact hole; and
filling said contact region opening with a metal layer to complete electrical connections.

2. The method according to claim 1, wherein said substrate comprises copper.

3. The method according to claim 1, wherein said dielectric layer is selected from the following material: oxide, borophosilicate glass, phosphosilicate glass, and borophosphosphosilicate glass.

4. The method according to claim 1, wherein said first barrier metal layer is selected from the following material: titanium (Ti), titanium nitride (TiN), tantalum nitride (TaN), tantalum tungsten (TaW), silicon nitride (Si₃N₄), and silicon oxynitride (SiON).

5. The method according to claim 1, wherein said first barrier metal layer is formed by anisotropically etching method.

6. The method according to claim 1, wherein thickness of said first barrier metal layer is greater than 100 angstrom.

7. The method according to claim 1, wherein said second conformal barrier layer is selected from the following material: titanium (Ti), titanium nitride (TiN), tantalum nitride (TaN), tantalum tungsten (TaW), silicon nitride (Si₃N₄), and silicon oxynitride (SiON).

8. The method according to claim 1, wherein said second conformal barrier metal layer is formed by anisotropically etching method.

9. The method according to claim 1, wherein thickness of said second conformal barrier metal layer is greater than 100 angstrom.

10. The method according to claim 1, wherein said metal layer is composed of a copper.

11. The method according to claim 1, wherein said metal layer is composed of a tungsten.

12. A method of fabricating a metal contact plug in a contact hole, the method comprising the steps of:
forming an dielectric layer over a substrate, said substrate having a contact region where said metal contact plug will be formed thereon, wherein said dielectric layer being selected from the group consisting of oxide, phosphosilicate glass, and borophosphosphosilicate glass;
depositing a first barrier layer over said dielectric layer, wherein said first barrier layer being selected from the group consisting of titanium (Ti), titanium nitride (TiN), tantalum nitride (TaN), tantalum tungsten (TaW), silicon nitride (Si₃N₄), and silicon oxynitride (SiON);
forming a patterned photoresist to defined a contact hole;
anisotropically etching said first barrier layer and said dielectric layer to expose a portion of said substrate by using said photoresist as a mask;
forming a contact hole in said dielectric layer, wherein the exposed substrate has a conductive region;
depositing a second conformal sacrificial layer on said first barrier layer and in said contact hole, wherein said second conformal sacrificial layer being selected from the group consisting of titanium (Ti), titanium nitride (TiN), tantalum nitride (TaN), tantalum tungsten (TaW), silicon nitride (Si₃N₄, and silicon oxynitride (SiON);
anisotropically etching said second conformal barrier layer to expose said conductive region and to form a spacer on sidewalls of in said contact hole;
filling said contact region opening with a metal layer to complete electrical connections; and
removing excess said metal layer.

13. The method according to claim 12, wherein said substrate comprises copper.

14. The method according to claim 12, wherein thickness of said first barrier metal layer is greater than 100 angstrom.

15. The method according to claim 12, wherein said second conformal barrier layer with a thickness about 100 angstroms.

16. The method according to claim 12, wherein said metal layer is composed of a copper.

17. The method according to claim 12, wherein said metal layer is composed of a tungsten.
